(19) United States
(12) Patent Application Publication
(10) Pub. No.: US 2007/0058456 A1
(43) Pub. Date: Mar. 15, 2007

(54) Integrated circuit arrangement

(76) Inventor: Rico Srowik, Dresden (DE)

Correspondence Address: SLATER & MATSIL LLP, 17950 PRESTON ROAD, SUITE 1000, DALLAS, TX, 75252, US

(21) Appl. No.: 11/223,900

(22) Filed: Sep. 9, 2005

(51) Int. Cl. G11C 7/10

(52) U.S. Cl. 365/189.08

(57) ABSTRACT

An integrated circuit arrangement comprises at least one circuit to be controlled and a control logic for controlling the at least one circuit to be controlled. Furthermore, a switch is connected between the circuit to be controlled and the control logic. The switch is adapted to connect the control logic to the circuit to be controlled in a first switching state and a programmable controller to be at least one circuit to be controlled in a second switching state.

### TECHNICAL FIELD

This invention relates generally to an integrated circuit arrangement.

### BACKGROUND

An integrated circuit 100, as shown in FIG. 1, may include a circuit to be controlled by another device. For example, in FIG. 1 a hard-wired control logic 102 is connected to a memory cell array 101 via a plurality of n conductor lines 103. The variable n is usually an integer value greater than 1, e.g. in the range of 2 to 65 or 128. The control logic 102 is connected upstream with a controlling device, which is external to the integrated circuit 100, via a plurality of m second conductor lines 104, wherein m is usually an integer value greater than 1, by means of which the hard-wired control logic 102 receives instructions from the external controlling device and generates control signals in response of the received instructions and sends the control signals via the first plurality of conductor lines 103 to the memory cell array 101, thereby controlling the memory cell components, i.e., the memory cells, for example. Examples of control signals are control signals for reading, programming or erasing one or a plurality of memory cells of the memory cell array 101.

Further, the integrated circuit 100 according to the prior art as shown in FIG. 1 suffers from a lack of flexibility with regard to the controllability of the memory cell array 101, e.g., with regard to test purposes or with regard to the updating or amending of the operation being performed by the control logic 102.

In other words, the integrated circuit 100 is limited in terms of controllability and flexibility by the fixedly predetermined and non-amendable hard-wired control logic 102. The control logic 102 restricts the circuit to be controlled 101 to certain predetermined control operations. For example, for test purposes or for checking additional operations not implemented in the control logic 102, there is a need to increase the controllability of the integrated circuit 100.

### SUMMARY OF THE INVENTION

The present invention provides a new integrated circuit for providing various functions depending on the character of a circuit to be controlled that is integrated in the integrated circuit, without the requirement to amend the hard-wired control logic, which is also integrated in the integrated circuit arrangement.

The integrated circuit arrangement according to a first aspect of the invention comprises at least one circuit to be controlled, at least one control logic for controlling the at least one circuit to be controlled, a switch being connected between the at least one circuit to be controlled and the control logic. The switch is adapted to connect, in a first switching stage, the control logic to the at least one circuit to be controlled. Furthermore, the switch is adapted to connect, in a second switching state, a programmable controller to the at least one circuit to be controlled.

According to a second aspect of the invention, the integrated circuit arrangement comprises at least one circuit to be controlled and a control logic for controlling the at least one circuit to be controlled. Furthermore, at least one programmable controller is provided and a switch, which is connected between the at least one circuit to be controlled and the control logic, on the one hand, and between the at least one circuit to be controlled and the programmable controller on the other hand. The switch is adapted to connect, in a first switching state, the control logic to the at least one circuit to be controlled. Furthermore, the switch is adapted to connect, in a second switching state, the programmable controller to the at least one circuit to be controlled.

According to a third aspect of the invention, at least one circuit to be controlled and a control logic for controlling the at least one circuit to be controlled are provided. Furthermore, at least one programmable controller and a switch are provided. The switch is connected between the at least one circuit to be controlled and the control logic, on the one hand, and between the at least one circuit to be controlled and the programmable controller, on the other hand. Further, a plurality of first conductor lines is connected between the control logic and a first input of the switch, a plurality of second conductor lines is coupled to a second input of the switch for connecting the programmable controller to the second input of the switch and a plurality of third conductor lines is connected between an output of the switch and an input of the at least one circuit to be controlled. A storage element is connected between one conductor line that can be connected to the programmable controller and the control input of the switch, wherein the switch is adapted to connect, in a first switching state, the control logic to the at least one circuit to be controlled, and, in a second switching state, the programmable controller to the at least one circuit to be controlled.

Embodiments of the invention clearly achieve an increased flexibility of the integrated circuit arrangement and in particular an improved controllability of the integrated circuit to be controlled.

These and other features of the invention will be better understood when taken in view of the following drawings and a detailed description.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates an integrated circuit arrangement in accordance with the prior art;

FIG. 2 illustrates an integrated circuit arrangement in accordance with a first embodiment of the present invention;

FIG. 3 illustrates an integrated circuit arrangement in accordance with a second embodiment of the invention;

FIG. 4A illustrates a first embodiment of the switch in accordance with the present invention;

FIG. 4B illustrates a second embodiment of the switch in accordance with the present invention; and

FIG. 4C illustrates a third embodiment of the switch in accordance with the present invention.

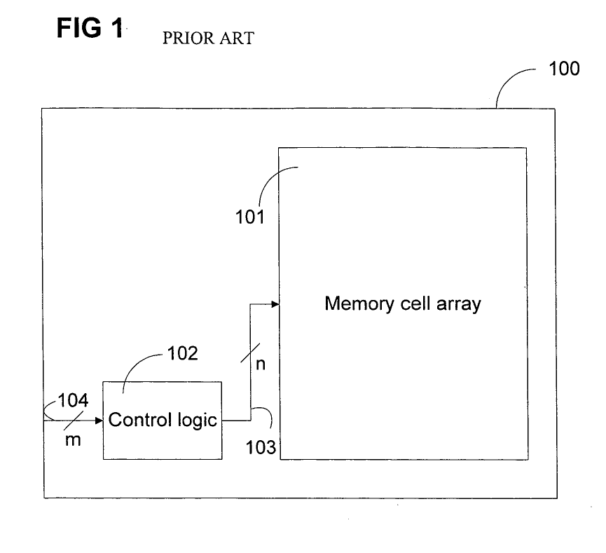

The following reference numerals are associated with the drawings.
100 integrated circuit arrangement
101 circuit to be controlled
102 control logic
103 conductor lines
104 conductor lines
200 integrated circuit arrangement
201 circuit to be controlled
202 control logic
203 first plurality of conductor lines
204 first external conductor lines
205 switch
206 second plurality of conductor lines
207 programmable controller
208 cables
209 control line
210 third plurality of conductor lines
211 first external interface
212 output control logic
217 control line
218 output programmable controller
219 control output programmable controller
220 input memory cell array
300 integrated circuit arrangement
301 second control conductor lines
302 input programmable controller
303 external interface
304 integrated control line
401 multiplexer
402 first input multiplexer
403 second input multiplexer
404 control input multiplexer
405 output multiplexer
406 control output control logic
407 storage element

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

According to one aspect of the invention, an integrated circuit arrangement is provided, which increases the controllability and flexibility of the circuit to be controlled, which is, e.g., monolithically integrated in the integrated circuit arrangement together with the control logic for controlling the circuit to be controlled.

Furthermore, a switch is also monolithically integrated in the integrated circuit arrangement, wherein the switch is connected between the circuit to be controlled and the control logic. The switch is adapted to connect the control logic to the at least one circuit to be controlled in a first switching state. In a second switching state, the switch is adapted to connect a programmable controller to the at least one circuit to be controlled.

According to another aspect of the invention, a plurality of first conductor lines is provided which is connected between the control logic and the first input of the switch. Furthermore, a plurality of second conductor lines is coupled to a second input of the switch for connecting a programmable controller to the second input of the switch. Moreover, a plurality of third conductor lines is connected between an output of the switch and an input of the at least one circuit to be controlled. In general, an arbitrary number of n switching elements can be provided in the switch, wherein one switching element is provided for each first conductor line. In other words, as many switching elements can be provided as there are first conductor lines. In this case, a first input of each switching element is connected to a respectively assigned first conductor line. Furthermore, a second input of each switching element is connected to a respectively assigned second conductor line for connecting a programmable controller to the second input of the switching element. Further, an output of each switching element is connected to a respectively assigned third conductor line for connecting the at least one circuit to be controlled to the output of the switching element.

However, in an alternative embodiment, the connections between the control logic and the switch, on the one hand, and the programmable controller and the switch, on the other hand, as well as between the switch and the circuit to be controlled, may be provided by means of an optical on-chip-connection, respectively. In this case, for example, the control logic comprises optical receivers to receive control signals from the external interface of the integrated circuit to receive instructions from an external microcontroller and also optical transmitters for transmitting optical signals to optical receivers provided in the switch. The switch further comprises second optical receivers for receiving optical signals from the programmable controller. In this case, the programmable controller also comprises optical transmitters for transmitting optical signals to the switch. In an alternative embodiment of the invention, only one optical receiver is provided which is adapted to receive optical signals from the control logic as well as from the programmable controller. According to this embodiment of the invention, the switch is adapted to receive only the respectively differently coded optical signals from either the control logic or from the programmable controller. Moreover, the circuit to be controlled also comprises optical receivers and/or transmitters for communicating with the switch and via the switch, with the control logic or the programmable controller.

According to another aspect of the invention, the programmable controller is monolithically integrated in the integrated circuit arrangement.

According to another aspect of the invention, the programmable controller is a microcontroller.

The control logic is, e.g., a hard-wired control logic, in general a control logic, the structure and functionality of which can only be amended with big efforts, if at all. In other words, the hard-wired control logic includes special electronic circuit elements, which are connected with each other such that the desired functionality of the control logic is provided.

The switch may have a control input via which the switch may be controlled by the programmable controller, in an alternative embodiment by means of the control logic or by means of an additional means, e.g., by means of an additional separate external or internal control means. The control input and the respective control signal being applied to the control input is used to switch the switch from the first switching state into the second switching state and vice versa.

Furthermore, the integrated circuit arrangement may comprise an additional storage element that may be connected between the programmable controller and the control input of the switch. The storage element may be implemented by means of a latch or by means of a flip flop, in general by means of any suitable, e.g., non-volatile, type of memory cell.

The storage element enables the unit that provides the switching control signal to the switch only to provide the raised active electrical signal for a rather short time to the storage element. Thus, the storage element is brought into a state representing the control signal. After the storage element has entered the state, it provides a steady-state-control signal to the switch without requiring the external control means to continuously provide a control signal. Therefore, only a control signal for changing the state of the storage element is needed from the control unit.

The switch may comprise or may be formed by a multiplexer.

The invention is particularly suitable for the application, wherein the at least one circuit to be controlled is a memory circuit, e.g. a non-volatile memory circuit. In accordance with this embodiment of the invention, the at least one circuit to be controlled may be a non-volatile memory circuit being selected from the group of:

a flash non-volatile memory circuit,

a ferroelectric random access memory (FeRAM) non-volatile memory circuit,

a magnet random access memory (MRAM) non-volatile memory circuit,

a phase change memory (PCM) non-volatile memory circuit,

a conductive bridging random access memory (CBRAM) non-volatile memory circuit, and

an organic random access memory (ORAM) non-volatile memory circuit.

It is to be noted that, although the invention will now be described with respect to a non-volatile memory cell array comprising a plurality of NROM (Nitride Read Only Memory) non-volatile flash memory cells, the invention is applicable to any suitable integrated circuit to be controlled, which is controlled by means of a control logic, wherein it is desired to increase flexibility and improved controllability of the circuit to be controlled.

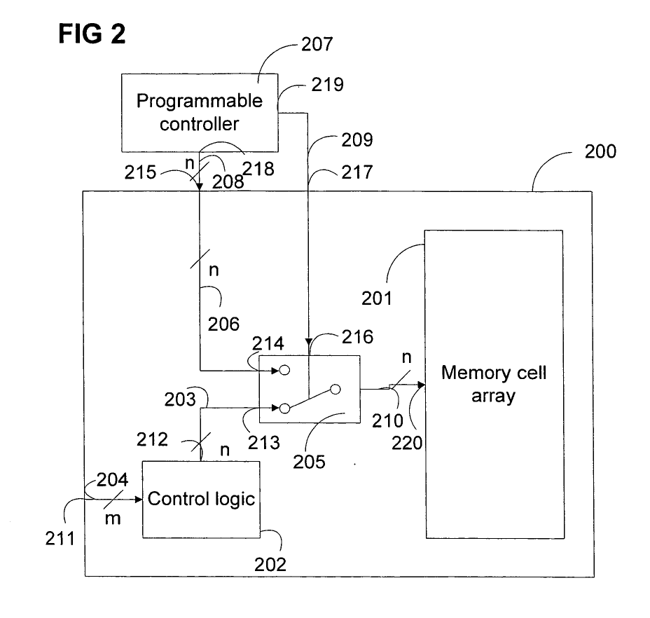

FIG. 2 shows an integrated circuit arrangement in accordance with a first embodiment of the invention.

An integrated circuit 200 comprises a monolithically integrated memory cell array 201 which comprises a plurality of memory cells that are arranged in columns and rows, wherein the memory cells are NROM memory cells. Thus, the memory cell array 201 is a Flash NROM memory cell array 201.

The control signals, e.g., for instructing read operation, for instructing write operation, for instructing erase operation or also for instructing test mode operations for testing the functionality of the memory cells in the memory cell array 201, are transmitted by means of data bus signals that are transmitted via a data bus including a plurality of n third conductor lines 210 (n≧1 or n>1 or n=2, 4, 8, 16, 32, 64, 128, 256, 512, 1024, for example), which are connected with an input 220 of the memory cell array 201.

Furthermore, the integrated circuit 200 comprises a hard-wired control logic 202, which is adapted to a predetermined functionality. By way of example, the hard-wired control logic 202 is adapted to perform one or a plurality of standard algorithm for controlling the memory cell array 201, e.g., one or a plurality of standard algorithms for controlling read operations, write operations, or erase operations.

Other examples of algorithms that may be implemented by the hard-wired control logic 202 are: one or a plurality of algorithms for addressing the memory cell array 201; one or a plurality of algorithms for providing a sequence for supplying voltages to the memory cell array 201; or one or a plurality of built-in self-test algorithms.

Furthermore, a switch 205 (which may include a plurality of switching elements) is provided in the integrated circuit 200.

An input of the control logic 202 is connected to an external interface 211 of the integrated circuit 200 via m external control conductor lines 204, wherein m≧1 or m>1 or m=2, 4, 6, 8, 16, 32, 64, 128, 256, 512, 1024, for example, and wherein m may be equal or non-equal to n.

An output 212 of the control logic 202 is connected with a first input 213 of the switch 205 via a first plurality of n conductor lines 203.

Furthermore, a second plurality of n conductor lines 206 is connected to a second input 214 of the switch 205 and with a second external interface 215 and therewith, by means of n cables 208, with a programmable controller 207, e.g., a microprocessor.

A control output 219 of the external programmable controller 207 is connected to a control input 216 of the switch 205 via a control line 217. With a plurality of switching elements being provided in the switch 205, each switching element has a respective switching element control input which is connected to a respective control line 217 so that each switching element can be individually controlled by means of the programmable controller 207.

In case a test operation, which is not implemented by means of the hard-wired control logic 202, is intended to be carried out, a respective control signal is generated by means of the programmable controller 207 and transmitted via the control lines 217 to the control input 206 of the switch 205, thereby activating the switch 205 such that the switch 205 is in a switching state such that the n lines of the second plurality of conductor lines 206 are connected directly to the n third plurality of conductor lines 210 and thus, the data signals generated by the programmable controller 207 are directly transmitted to the memory cell array 201. The same holds true in case that any other suitable or desired operation/algorithm is intended to be carried out on the memory cell array 201.

In normal operation mode, in which the memory cell array 201 is controlled by means of the hard-wired control logic 202, the switch 205 is controlled by the programmable controller 207 such that it is in a switching state such that the signals generated by the control logic 202 and transmitted via the n first plurality of conductor lines 203 are directly transmitted to the memory cell array 201 via the third plurality of conductor lines 210.

Since the first plurality of conductor lines 203, the second plurality of conductor lines 206 and the third plurality of conductor lines 210 all have the same number of conductor lines, each conductor line of the first plurality of conductor lines 203 is connected to a respective one of the conductor lines of the third plurality of conductor lines 210 in case that the switch 205 is in a first switching state, and each conductor line of the second plurality of conductor lines 206 is connected to a respective one conductor line of the third plurality of conductor lines 210 in case that the switch 205 is controlled to be in a second switching state. In other words, each switching element is individually connected to a respective first conductor line (by means of its respective first input), to a respective second conductor line (by means of its respective second input), and each switching element is individually controllable with regard to its respective switching status.

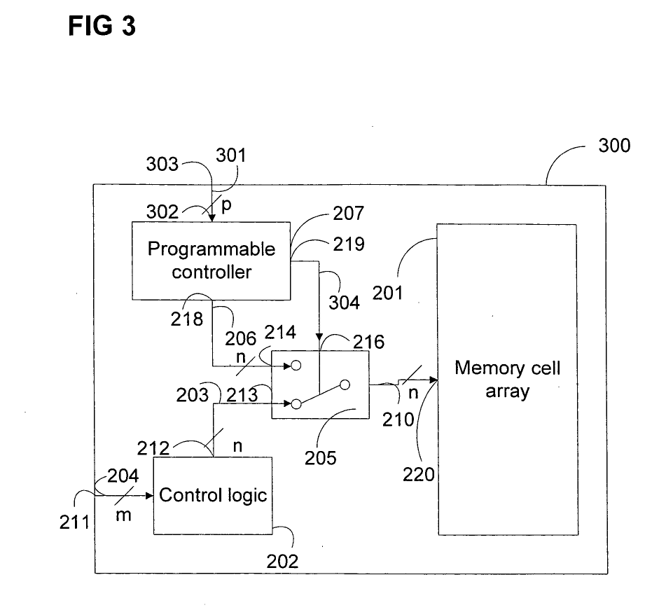

FIG. 3 shows an integrated circuit 300 in accordance with a second embodiment of the present invention.

The second embodiment is similar to the first embodiment of the invention. The same previously identified elements remain their reference numerals.

The integrated circuit arrangement 300 in accordance with the second embodiment of the invention differs from the integrated circuit arrangement 200 in accordance with the first embodiment of the invention mainly in that the programmable controller 207, that is, e.g., the microprocessor 207, is also monolithically integrated on the integrated circuit arrangement 300 together with the hard-wired control logic 202, the switch 205 and the memory cell array 201.

Thus, second external control conductor lines 301 are provided which connect an input 302 of the programmable controller 207 with a second external interface 303 of the integrated circuit arrangement 300. The p second control conductor lines 301 (p=1, 2, 4, 8, 16, 32, 64, 128, 256, 512, for example) enables the external activation of the programmable controller 207 by means of a further controlling device, e.g., a personal computer or any other suitable control device such as a laptop, a notebook, a special purpose computer, a personal digital assistant computer, etc.

Furthermore, the control connection between the programmable controller 207 and the switch 205 is provided by means of an integrated switch control conductor line 304.

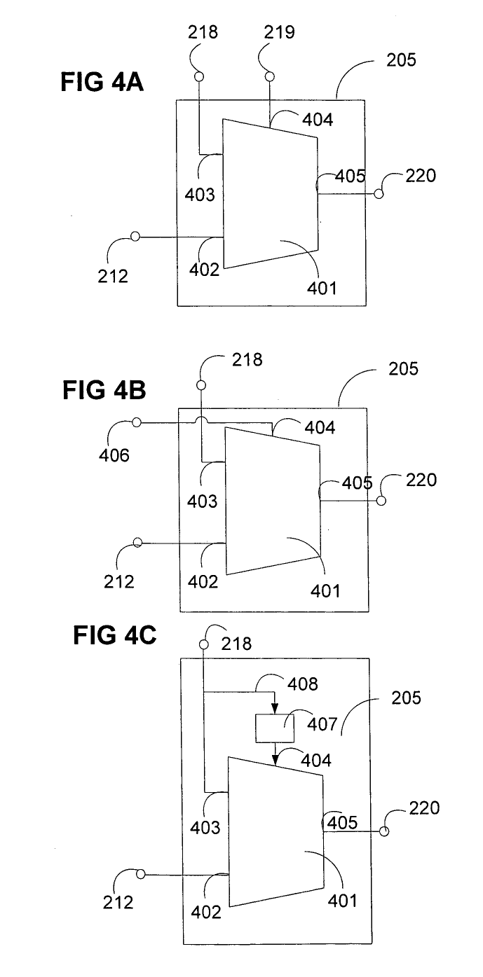

FIG. 4A shows a first implementation of the switch 205.

In accordance with a first possible implementation of the switch 205, a multiplexer 401 is provided, wherein a first data input 402 of which is connected to the output 212 of the control logic 202 and a second data input 403 of which is connected with the output 218 of the programmable controller 207. A control input 404 of the multiplexer 401 is connected to the control output 219 of the programmable controller 207. Furthermore, the output 405 of the multiplexer 401 is connected to the input 220 of the memory cell array 201.

FIG. 4B shows a second alternative of an embodiment of the switch 205, wherein the switch 205 is also implemented by means of the multiplexer 401, however, with a different connection scheme as compared to the multiplexer 401 that is shown in FIG. 4A.

The difference can mainly be seen in that the control input 404 of the multiplexer 401 in this case is connected to a control output 406 of the hard-wired control logic 202 (not shown in FIG. 2 and FIG. 3). In other words, in accordance with this embodiment of the invention, the switch 205 is controlled by means of the hard-wired control logic 202.

FIG. 4C shows a third embodiment of the switch 205, wherein the switch 205 further comprises a storage element 407, in accordance with this embodiment of the invention, e.g., implemented by means of a latch or by means of a flip flop, wherein the storage element 407 is connected between a control line 408 which is connected to the output 218 of the programmable controller 207 and the control input 404 of the multiplexer 401.

Thus, the switch control signal generated by the programmable controller 207 is latched by means of the storage element 407 and thus, the state of the storage element 407 is used as the control input for the multiplexer 401.

In summary, according to one aspect of the invention, additional signal lines are inserted into the integrated circuit arrangement that are controlled by a programmable controller, e.g., a microcontroller, using appropriate software, that is an appropriate computer program, for carrying out operations that are not implemented in the hard-wired control logic 202 and which are to be carried out on the memory cell array 201, more accurate, on the memory cells of the memory cell array 201. This is achieved by means of an additionally inserted circuitry that selects, if either the signal of the hard-wired control circuit (control logic 202) or the signals generated by means of the programmable controller 207 should be used to control the circuitry being controlled, e.g., the memory cell array 201.

The microcontroller software is now able to select, if the hard-wired operations that are implemented in the hard-wired control logic 202 or the operation implemented in the programmable controller 207 by means of computer programs are used for controlling the circuit to be controlled. The operation mode as well as the operations themselves can thus be changed by adapting software only in the programmable controller 207.

Thus, it is now possible to control the circuit to be controlled directly with a programmable controller, e.g., a microcontroller, and change the operation of the circuit with software.

The inserted freely configurable switches (there may be one switch provided for each of the n conductor lines) are provided between the output 212 of the control logic and the input 220 of the memory cell array. With those switches, it can be selected if either the output signals of the hard-wired logic control 202 is used to control the circuit to be controlled or if signals directly provided by the programmable controller are used to control the circuit to be controlled 201. The state of the switching elements of the switch 205 is controlled, e.g., by means of the programmable controller 207, e.g., a microcontroller, allowing the microcontroller software to change the state of the switching elements of the switch 205, if desired. After changing the state of the switching elements of the switch 205, the circuit to be controlled 201 can directly be controlled by means of the microcontroller 207. Thus, a change of a circuit operation can now easily be performed by adapting the microcontroller software.

Clearly this means that it is now possible to bypass the internal hard-wired control logic 202 by changing microcontroller signals.

The foregoing description has been presented for purposes of illustration and description. It is not intended to be exhaustive or to limit the invention to the precise form disclosed, and obviously many modifications and variations are possible in light of the disclosed teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

What is claimed is:

1. An integrated circuit arrangement, comprising:
at least one circuit to be controlled;
at least one control logic for controlling the at least one circuit to be controlled; and
at least one switch being coupled between the at least one circuit to be controlled and the control logic, wherein the switch is adapted to couple, in a first switching state, the control logic to the at least one circuit to be controlled, and, in a second switching state, a programmable controller to the at least one circuit to be controlled.

2. The integrated circuit arrangement of claim 1, further comprising:
a plurality of first conductor lines being coupled between the control logic and a first input of the switch;
a plurality of second conductor lines coupled to a second input of the switch for coupling a programmable controller to the second input of the switch; and
a plurality of third conductor lines coupled between an output of the switch and an input of the at least one circuit to be controlled.

3. The integrated circuit arrangement of claim 1, wherein the programmable controller is integrated in the integrated circuit arrangement.

4. The integrated circuit arrangement of claim 1, wherein the programmable controller comprises a microcontroller.

5. The integrated circuit arrangement of claim 1, wherein the control logic comprises hard-wired control logic.

6. The integrated circuit arrangement of claim 1, wherein a control input of the switch is coupled to at least one conductor line that can be coupled to the programmable controller.

7. The integrated circuit arrangement of claim 6, further comprising a storage element that is coupled between the programmable controller and the control input of the switch.

8. The integrated circuit arrangement of claim 7, wherein the storage element comprises a latch or a flip flop.

9. The integrated circuit arrangement of claim 1, wherein the switch comprises a multiplexer.

10. The integrated circuit arrangement of claim 1, wherein the at least one circuit to be controlled comprises a memory circuit.

11. The integrated circuit arrangement of claim 10, wherein the at least one circuit to be controlled comprises a non-volatile memory circuit.

12. The integrated circuit arrangement of claim 11, wherein the at least one circuit to be controlled comprises a non-volatile memory circuit being selected from the group consisting of:
a flash non-volatile memory circuit;
a ferroelectric random access memory non-volatile memory circuit;
a magnetic random access memory non-volatile memory circuit;
a phase change memory non-volatile memory circuit;
a conductive bridging random access memory non-volatile memory circuit; and
an organic random access memory non-volatile memory circuit.

13. An integrated circuit arrangement, comprising:
at least one circuit to be controlled;
a control logic for controlling the at least one circuit to be controlled;
at least one programmable controller; and
a switch being coupled between the at least one circuit to be controlled and the control logic, and between the at least one circuit to be controlled and the programmable controller,
wherein the switch is adapted to couple, in a first switching state, the control logic to the at least one circuit to be controlled, and, in a second switching state, the programmable controller to the at least one circuit to be controlled.

14. The integrated circuit arrangement of claim 13, wherein the control logic comprises hard-wired control logic.

15. The integrated circuit arrangement of claim 14, wherein the programmable controller comprises a microcontroller.

16. The integrated circuit arrangement of claim 15, wherein the at least one circuit to be controlled, the at least one control logic and the at least one switch are all integrated on a single semiconductor substrate.

17. The integrated circuit arrangement of claim 13, wherein the switch comprises a multiplexer.

18. The integrated circuit arrangement of claim 13, wherein the at least one circuit to be controlled comprises a memory circuit.

19. The integrated circuit arrangement of claim 18, wherein the at least one circuit to be controlled comprises a non-volatile memory circuit.

20. An integrated circuit arrangement, comprising:
at least one circuit to be controlled;
a control logic for controlling the at least one circuit to be controlled;
at least one programmable controller;
a switch being coupled between the at least one circuit to be controlled and the control logic, and between the at least one circuit to be controlled and the programmable controller;
a plurality of first conductor lines being coupled between the control logic and a first input of the switch;
a plurality of second conductor lines being coupled between the programmable controller and a second input of the switch;
a plurality of third conductor lines coupled between an output of the switch and an input of the at least one circuit to be controlled; and
a storage element being coupled between at least one conductor line that can be coupled to the programmable controller and the control input of the switch,
wherein the switch is adapted to couple, in a first switching state, the control logic to the
at least one circuit to be controlled, and, in a second switching state, the programmable controller to the at least one circuit to be controlled.
